(19) United States
(12) Patent Application Publication
(10) Pub. No.: US 2025/0379076 A1
(43) Pub. Date: Dec. 11, 2025

(54) Load Lock Chamber for Workpiece Processing

(71) Applicants: Beijing E-Town Semiconductor Technology Co., Ltd., Beijing (CN); Mattson Technology, Inc., Fremont, CA (US)

(72) Inventors: Hari Ambal, San Jose, CA (US); Kyle Barrette, Gilbert, AZ (US); Alex Viel, Santa Clara, CA (US)

(21) Appl. No.: 19/217,589

(22) Filed: May 23, 2025

Related U.S. Application Data
(60) Provisional application No. 63/657,299, filed on Jun. 7, 2024.

(51) Int. Cl. H01L 21/67; H01L 21/687; H05B 3/00

(52) U.S. Cl. CPC H01L 21/67201; H01L 21/67115; H01L 21/68707; H05B 3/0033

(57) ABSTRACT

A load lock chamber of a workpiece processing apparatus is provided. The load lock chamber includes a workpiece handling robot comprising a first arm configured to transfer a workpiece along a first plane to and from a thermal processing region defined within the load lock chamber. The load lock chamber further includes a thermal processing assembly configured to thermally process the workpiece when the workpiece is positioned within the thermal processing region defined within the load lock chamber. The workpiece handling robot is further configured to transfer the workpiece along the first plane to a processing chamber of the workpiece processing apparatus.

### PRIORITY CLAIM

The present application is based on and claims priority to U.S. Provisional Application 63/657,299 having a filing date of Jun. 7, 2024, which is incorporated by reference herein.

### FIELD

The present disclosure relates generally to processing workpieces and more particularly to systems for processing workpieces, such as semiconductor workpieces.

### BACKGROUND

Processing systems which expose workpieces such as, semiconductor wafers or other suitable substrates, to an overall manufacturing scheme of fabricating semiconductor devices or other devices can perform a plurality of manufacturing process steps, such as patterning, film deposition (e.g., chemical vapor deposition, physical vapor deposition, plasma enhanced vapor deposition), film removal (e.g., dry etch, dry strip, wet etch), ion implantation, thermal treatment, surface cleaning, surface treatment (e.g. oxidation, nitridation, surface wetting angle tuning), etc. Many of these manufacturing steps occur in a vacuum or near vacuum pressure. Different vacuum processing chambers can have different designs and configurations. To carry out these treatment steps, a system may include one or more workpiece handling robots to move workpieces a number of different times, for example, into the system, between various processing chambers, and out of the system.

### SUMMARY

Aspects and advantages of embodiments of the present disclosure will be set forth in part in the following description, or may be learned from the description, or may be learned through practice of the embodiments.

One example aspect of the present disclosure is directed to a load lock chamber of a workpiece processing apparatus. The load lock chamber includes a workpiece handling robot comprising a first arm configured to transfer a workpiece along a first plane to and from a thermal processing region defined within the load lock chamber. The load lock chamber further includes a thermal processing assembly configured to thermally process the workpiece when the workpiece is positioned within the thermal processing region defined within the load lock chamber. The workpiece handling robot is further configured to transfer the workpiece along the first plane to a processing chamber of the workpiece processing apparatus.

Another example aspect of the present disclosure is directed to a method for thermally processing a workpiece within a load lock chamber of a workpiece processing apparatus. The method includes receiving a workpiece from a front end portion of the workpiece processing apparatus. The method further includes transferring the workpiece along a first plane with a workpiece handling robot to a thermal processing region defined within the load lock chamber. The method further includes thermally processing the workpiece within the thermal processing region while the workpiece is on an end effector of the workpiece handling robot. The method further includes transferring the workpiece along the first plane to a processing chamber of the workpiece processing apparatus.

Another example aspect of the present disclosure is directed to a workpiece processing apparatus. The workpiece processing apparatus includes a front end portion configured to house one or more workpieces. The workpiece processing apparatus further includes a processing chamber comprising a first processing position. The workpiece processing apparatus further includes a load lock chamber. The load lock chamber includes a first workpiece handling robot configured to transfer a first workpiece along one or more first planes to and from a first thermal processing region defined within the load lock chamber. The load lock chamber further includes a first thermal processing assembly configured to thermally process the first workpiece when the first workpiece is positioned within the first thermal processing region defined within the load lock chamber. The first workpiece handling robot is further configured to transfer the first workpiece along the one or more first planes to the processing chamber of the workpiece processing apparatus.

Other example aspects of the present disclosure are directed to systems, methods, and apparatus for processing semiconductor workpieces.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example workpiece processing apparatus according to example embodiments of the present disclosure;

FIG. 2 depicts a top down interior view of an example load lock chamber according to example embodiments of the present disclosure;

FIG. 3 depicts a top down exterior view of an example load lock chamber according to example embodiments of the present disclosure;

FIG. 4A depicts an exploded view of an example thermal processing assembly according to example embodiments of the present disclosure;

FIG. 4B depicts thermally processing a workpiece within a load lock chamber according to example embodiments of the present disclosure;

FIG. 5 depicts a top down view of another example thermal processing assembly according to example embodiments of the present disclosure;

FIG. 6 depicts an example workpiece handling robot according to example embodiments of the present disclosure;

FIGS. 7A and 7B depict an example workpiece support according to example embodiments of the present disclosure;

FIG. 8 depicts an example gas system according to example embodiments of the present disclosure; and

FIG. 9 depicts an example method for thermally processing a workpiece within a load lock chamber according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

A workpiece processing apparatus may include a load lock chamber in process flow communication with one or more processing chambers. In general, the one or more processing chambers may implement a variety of workpiece manufacturing processes to process workpieces, such as semiconductor workpieces. Some processing chamber designs include additional chambers such as transfer chambers with workpiece handling equipment configured to, for example, transfer a workpiece from a load lock chamber or within a load lock chamber to a processing chamber.

Aspects of the present disclosure are directed to a load lock chamber for a workpiece processing apparatus. The load lock chamber of the present disclosure includes workpiece handling equipment positioned within the load lock chamber configured to transfer a workpiece to a processing chamber of the workpiece processing apparatus. Furthermore, the load lock chamber includes one or more thermal processing assemblies configured to thermally process the workpiece when the workpiece is positioned within the thermal processing region defined within the load lock chamber. For instance, the load lock chamber may include one or more thermal processing assemblies for thermally processing a semiconductor workpiece while a workpiece is still being handled by the workpiece handling robot (e.g., is on an end effector for the workpiece handling robot).

Aspects of the present disclosure provide many technical effects and benefits. For example, workpiece handling equipment defined within the load lock chamber allows for the transfer of workpieces from the load lock chamber directly to a processing chamber without the need for an additional transfer chamber. In addition, workpieces may be thermally processed within the load lock chamber.

Variations and modifications can be made to these example embodiments of the present disclosure. As used in the specification, the singular forms “a,” “and,” and “the” include plural referents unless the context clearly dictates otherwise. The use of “first,” “second,” “third,” and “fourth” are used as identifiers and are directed to an order of processing. Example aspects may be discussed with reference to a “substrate,” “wafer,” or “workpiece” for purposes of illustration and discussion. Those of ordinary skill in the art, using the disclosures provided herein, will understand that example aspects of the present disclosure can be used with any suitable workpiece. The use of the term “about” in conjunction with a numerical value refers to within 20% of the stated numerical value. As used herein, “near vacuum” refers to less than about 10 Torr.

With reference now to the FIGS., example embodiments of the present disclosure will now be discussed in detail.

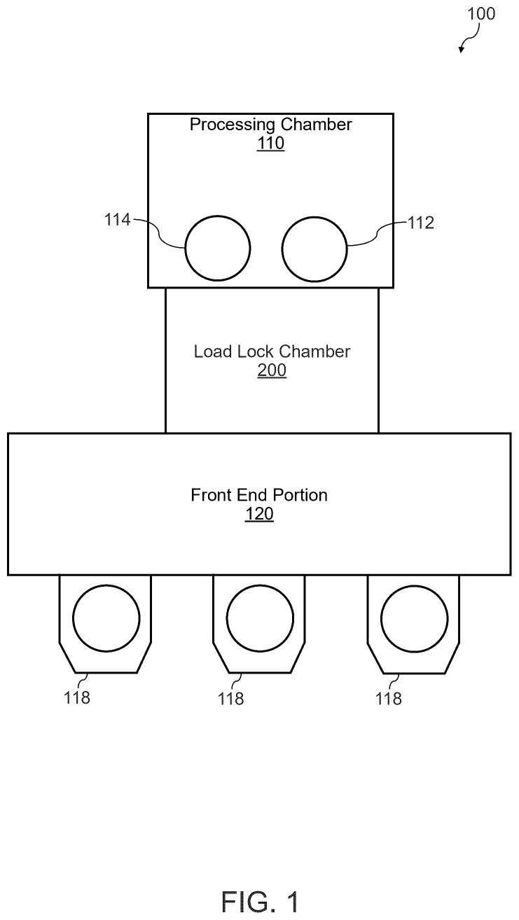

FIG. 1 depicts a workpiece processing apparatus according to example embodiments of the present disclosure. As shown in FIG. 1, workpiece processing apparatus 100 includes a front end portion 120, a load lock chamber 200, and a processing chamber 110.

Front end portion 120 is configured to house one or more workpieces. Front end portion 120 may be configured to be maintained, for example, at atmospheric pressure. Further, front end portion 120 may be configured to engage workpiece input devices 118. Workpiece input devices 118 may include, for instance, cassettes, front opening unified pods, or other devices for supporting a plurality of workpieces. Workpiece input devices 118 may be used to provide pre-process workpieces to the workpiece processing apparatus 100 or to receive post-process workpieces from workpiece processing apparatus 100.

The front end portion 120 can include one or more workpiece handling robots (not illustrated) for transferring workpieces from workpiece input devices 118 to, for instance, the load lock chamber 200, such as to and from a workpiece support defined within the load lock chamber 200. In some embodiments, a workpiece handling robot in the front end portion 120 can transfer preprocess workpieces to the load lock chamber 200 and can transfer post-process workpieces from the load lock chamber 200 to one or more of the workpiece input devices 118. Any suitable robot (e.g., workpiece transferring system) for transferring workpieces may be used in the front end portion 120 without deviating from the scope of the present disclosure. Workpieces may be transferred to and or from the load lock chamber 200 through a suitable slit, opening, or aperture.

Load lock chamber 200 is positioned between front end portion 120 of the workpiece processing apparatus 100 and the processing chamber 110 of the workpiece processing apparatus 100. Load lock chamber 200 may be configured to adjust the pressure surrounding the workpieces from the pressure associated with front end portion 120 to a process pressure, such as a vacuum or near vacuum pressure or other process pressure, prior to transfer of the workpieces to processing chamber 110 (e.g., a processing position 112, 114 defined within processing chamber 110). In some embodiments, load lock chamber 200 may be operable at a pressure from about 10 torr (or less) to atmospheric pressure.

Accordingly, a workpiece may be transferred from load lock chamber 200 to processing chamber 110 (e.g., a processing position 112, 114 defined within processing chamber 110). Processing chamber 110 may be used to perform any of a variety of workpiece processing on a workpiece, such as vacuum anneal processes, surface treatment processes, dry strip processes, dry etch processes, deposition processes, and other processes. For example, processing chamber 110 may be one or more of an etch process chamber, a dry strip process chamber, a deposition process chamber, a thermal process chamber (e.g., an anneal process chamber), an ion implantation process chamber, or a surface treatment process chamber. In some embodiments, processing chamber 110 may include plasma-based process sources such as, for example, inductively coupled plasma (ICP) sources, microwave sources, surface wave plasma sources, ECR plasma sources, and capacitively coupled (parallel plate) plasma sources. In some embodiments, processing chamber 110 may be operable at a pressure of less than about 10 torr. In some embodiments, processing chamber 110 may be selectively sealed off from, for example, load lock chamber 200 during processing.

As illustrated in FIG. 1, processing chamber 110 may include one or more workpiece processing positions 112, 114. In some embodiments, processing chamber 110 may be defined as a dual workpiece processing chamber, including a first processing position 112 and a second processing position 114. As shown, processing positions 112, 114 may be in a side-by-side arrangement such that a pair of workpieces may be simultaneously exposed to the same process. Each processing position 112, 114 may include a workpiece support (e.g., a pedestal) for supporting a workpiece during processing. In some embodiments, each processing position 112, 114 of processing chamber 110 may share a common pedestal with two portions for supporting a workpiece.

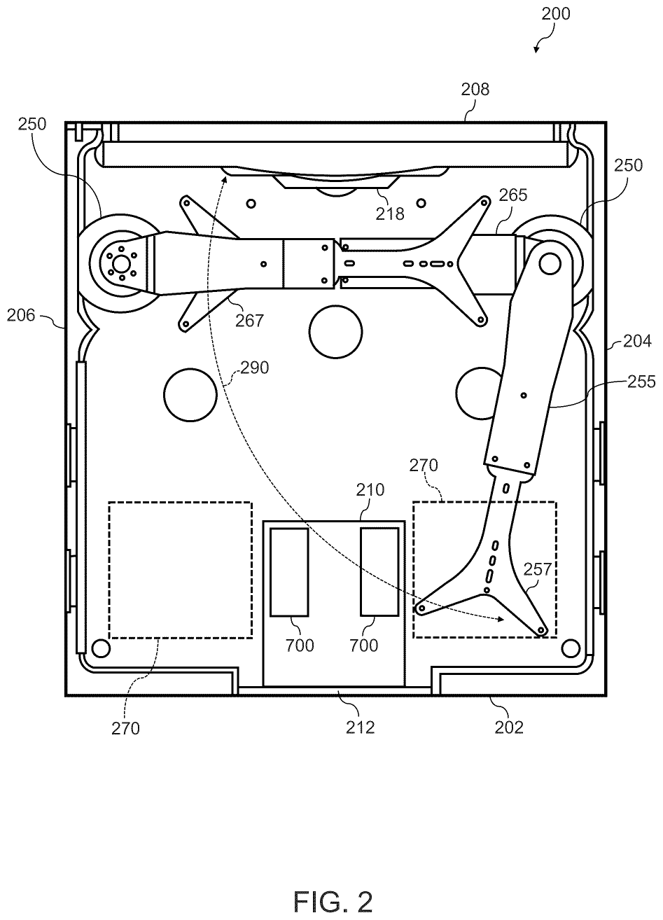

Referring now to FIG. 2, a top down interior view of a load lock chamber according to example embodiments of the present disclosure is depicted. Load lock chamber 200 may be implemented in a workpiece processing apparatus, such as workpiece processing apparatus 100 of FIG. 1. Specifically, load lock chamber 200 may be positioned between a front end portion of a workpiece processing apparatus and the processing chamber of the workpiece processing apparatus.

Load lock chamber 200 includes one or more workpiece handling robots 250 defined within the interior of the load lock chamber 200. Workpiece handling robot 250 includes an arm 255. Workpiece handling robot 250 may further include an end effector 257 coupled to arm 255. End effector 257 is configured to pick up, support, and/or drop off one or more workpieces. As shown in FIG. 2, arm 255 (e.g., and end effector 257) is configured to transfer a workpiece along a first plane. As shown, arm 255 may rotate about an axis such that end effector 257 (e.g., end effector 257 and workpiece) may follow path 290.

In some embodiments, workpiece handling robot 250 may include a second arm 265 defined by a second plane. The second arm 265 may rotate about the same axis as arm 255. Accordingly, the second arm 265 (e.g., and end effector 267) may move along a second plane that is parallel to the first plane. For example, the second arm 265 may be positioned below first arm 255 such that the second arm moves along a plane below the first plane of arm 255. Furthermore, both end effector 257 of arm 255 and end effector 267 of arm 265 may follow path 290.

As previously discussed, load lock chamber 200 may include a workpiece support 210 configured to hold one or more workpieces. Specifically, workpiece support 210 may include one or more of shelves 700, each shelf configured to hold a workpiece. The workpiece support 210 may receive pre-processed workpieces from a front end portion, such as front end portion 120 depicted in FIG. 1. For example, a workpiece handling system (e.g., robot) of a front end portion may be configured to place pre-processed workpieces onto the workpiece support 210 (e.g., shelves 700 of the workpiece support 210). In some embodiments, shelves 700 may be offset to a side of the load lock chamber 200. For example, a workpiece handling system (e.g., robot) of, for example, a front end portion may be configured to place pre-processed workpieces directly onto a first shelf 700 offset to a first side of load lock chamber 200 and/or a second shelf 700 offset to a second side of load lock chamber 200. Accordingly, load lock chamber 200 may not include central shelves and/or a central lift device.

In some embodiments, the shelves 700 may be movable shelves. For example, shelves 700 may be movable such that arm 255 (e.g., with end effector 257) may move freely along path 290 from thermal processing region 270 to a processing chamber (e.g., through opening 218).

Load lock chamber 200 further includes one or more thermal processing regions 270. Thermal processing regions 270 may be defined as a spaces within load lock chamber 200 where a workpiece may be thermally processed (e.g., heated and/or cooled). Workpiece handling robot 250 is configured to transfer a workpiece to and from a thermal processing region 270 defined within load lock chamber 200. For example, workpiece handling robot 250 may be configured to transfer a workpiece held by workpiece support 210 to a thermal processing region 270. Furthermore, the workpiece handling robot 250 may transfer the workpiece from thermal processing region 270 to a processing chamber (e.g., processing position defined within processing chamber) such as processing chamber 110 depicted in FIG. 1.

As shown in FIG. 2, load lock chamber 200 may be defined by sidewalls 202, 204, 206, and 208. Sidewall 202 may include an opening 212 (e.g., slit, slit door) through which a workpiece may be transferred from, for example, a front end module such as front end portion 120 (FIG. 1). Further, sidewall 208 may include an opening 218 (e.g., slit, slit door) through which a workpiece may be transferred to, for example, a processing chamber such as processing chamber 110 (FIG. 1). Opening 218 and opening 212 may be positioned on opposite sidewalls 202, 208 of load lock chamber 200. One or more workpiece handling robots 250 may be configured to transfer a workpiece to, for example, a processing station defined within a processing chamber. For example, arms 255, 265 may move end effectors 257, 267 to a position proximate opening 218. End effectors 257, 267 may then extend (e.g., in a direction defined by arms 255, 265) through opening 218 to, for example, deposit a workpiece on a processing station defined within the processing chamber.

In some embodiments, load lock chamber 200 may include a plurality of workpiece handling robots with a plurality of arms 255, 265. For example, a first workpiece handling robot 250 may be defined proximate sidewall 204, while a second workpiece handling robot 250 may be defined proximate sidewall 206. In some embodiments, each workpiece handling robot 250 of the load lock chamber 200 may correspond to a single thermal processing region 270. For example, a first workpiece handling robot 250 positioned proximate sidewall 204 may be configured to transfer a workpiece to a first thermal processing region 270 positioned proximate sidewall 204. Furthermore, a second workpiece handling robot 250 positioned proximate sidewall 206 may be configured to transfer a workpiece to a second thermal processing region 270 positioned proximate sidewall 206.

In further embodiments, each workpiece handling robot 250 of load lock chamber 200 may correspond to a single processing position within a processing chamber. For example, first workpiece handling robot 250 positioned proximate sidewall 204 may be configured to transfer a workpiece to a first processing position within a processing chamber, such as first processing position 112 of processing chamber 110 described above with reference to FIG. 1. Furthermore, second workpiece handling robot 250 positioned proximate sidewall 206 may be configured to transfer a workpiece to a second processing position within a processing chamber, such as second processing position 114 of processing chamber 110 described above with reference to FIG. 1.

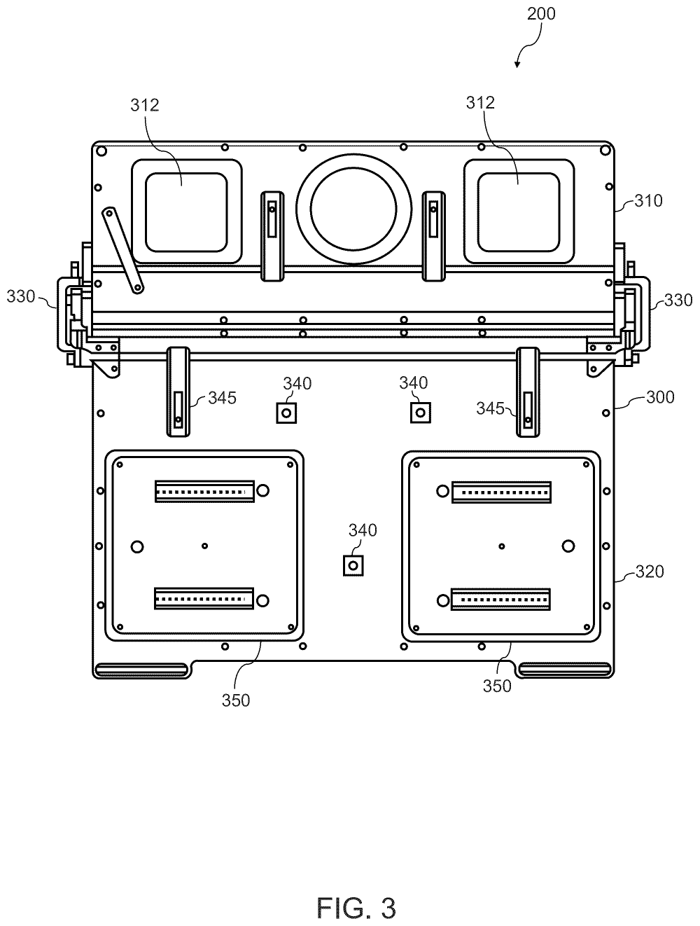

Referring now to FIG. 3, a top down exterior view of load lock chamber 200 is provided. Specifically, FIG. 3 illustrates the lid 300 (e.g., external surface) of load lock chamber 200. Lid 300 may be defined as a split lid design. For example, lid 300 may include a first lid portion 310 corresponding to (e.g., covering) the one or more workpiece handling robots 250 (FIG. 2), and a second lid portion 320 corresponding to (e.g., covering) the one or more thermal processing regions 270 (FIG. 2). In some embodiments, hinges 330 may connect the first lid portion 310 to the second lid portion 320. First lid portion 310 may include quartz windows 312. Wafer position sensors 340 (e.g., displacement sensors) and arm position sensors 345 may be positioned on lid 300, such as on second lid portion 320. The load lock chamber 200 may include other sensors without deviating from the scope of the present disclosure. Second lid portion 320 further includes one or more thermal processing assemblies 350 corresponding to the thermal processing regions 270 (FIG. 2).

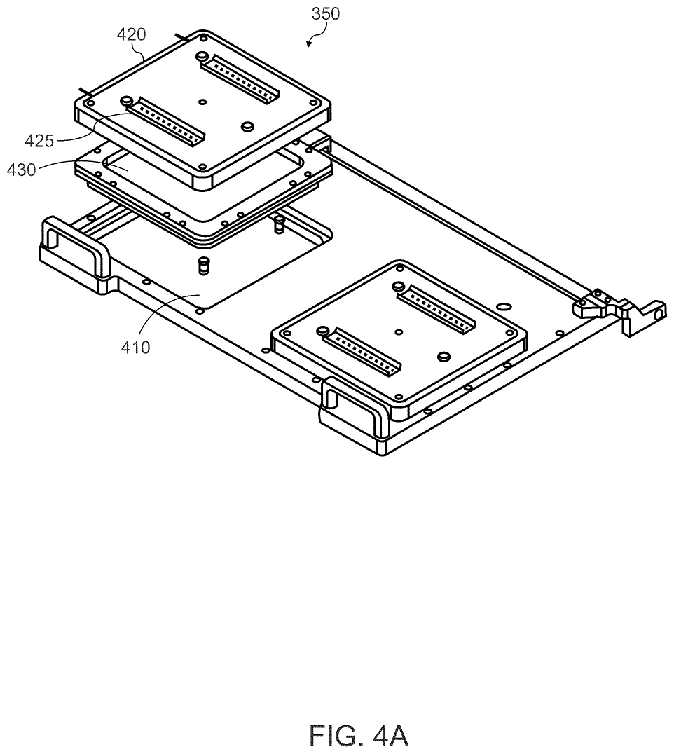

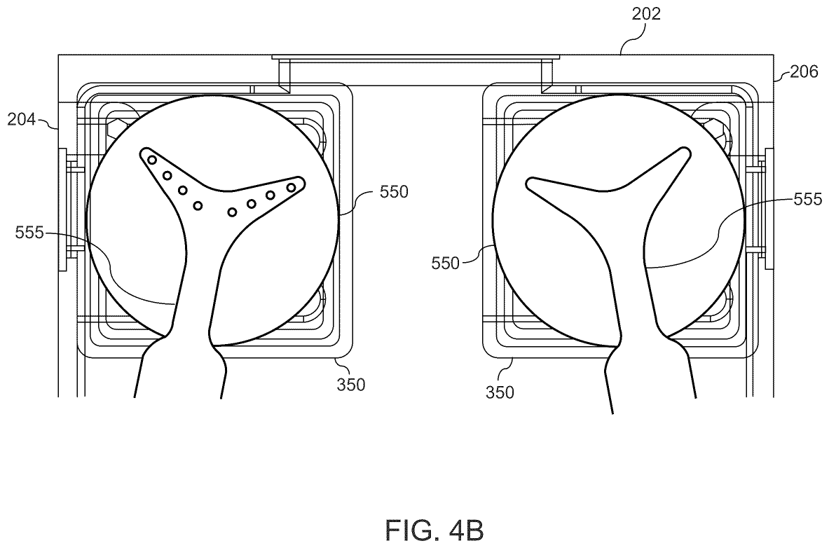

Referring now to FIG. 4, an exploded view of an example thermal processing assembly 350 is depicted. As shown in FIG. 4, load lock chamber 200 (e.g., lid 300 of load lock chamber) may include a hole 410. A thermal processing assembly 350 may be mounted within hole 410. Thermal processing assembly 350 and hole 410 may be rectangular. Accordingly, the corresponding thermal processing region 270 (FIG. 2) may also be rectangular.

As shown in FIG. 4, thermal processing assembly 350 may include a light source assembly 420. In some embodiments, light source assembly 420 may be an infrared light source assembly. The light source assembly 420 may include one or more light sources 425 (e.g., lamps, LEDs, etc). Thermal processing assembly 350 further includes window 430, such as a quartz window. Light source assembly 420 is configured to thermally process (e.g., heat) a workpiece defined within a load lock chamber through window 430. As such, light source assembly 420 may be mounted atop window 430.

Referring now to FIG. 4B, thermal processing of a workpiece within a load lock chamber, such as load lock chamber 200 of FIG. 2 is illustrated. Specifically, FIG. 4B provides a bottom up view of a workpiece handling robot (e.g., end effector 555 of a workpiece handling robot) supporting a workpiece 550 under a thermal processing assembly 350. As previously discussed, a thermal processing assembly 350 may define a thermal processing region within a load lock chamber where a workpiece may be thermally processed (e.g., heated).

Workpiece 550 may be held in a thermal processing region by an end effector 555 of a workpiece handling robot, such as workpiece handling robot 250 of FIG. 2. As such, the workpiece 550 may be thermally processed (e.g., heated) by a thermal processing assembly 350.

As shown in FIG. 4B, workpiece 550 may be thermally processed while the workpiece 550 is held by end effector 555. For example, end effector 555 may support workpiece 550 by contacting a bottom surface of the workpiece 550 such that the workpiece 550 is positioned between the thermal processing assembly 350 and end effector 555. As such, the surface of the workpiece 550 not in contact with the end effector 555 (e.g., the top surface) is directly exposed to heat provided by the thermal processing assembly 350. Thermal processing of the workpiece while being held by the workpiece handling robot (e.g., end effector 555) allows for faster and more efficient thermal processing of the workpiece.

In some embodiments, the load lock chamber may provide for cooling of the workpiece 550 while on the workpiece handling robot (e.g., end effector 555 of workpiece handling robot). For instance, a cooling system may be operable to transfer heat away from the workpiece 550. The cooling system may include a fluid based cooling system or other suitable cooling system.

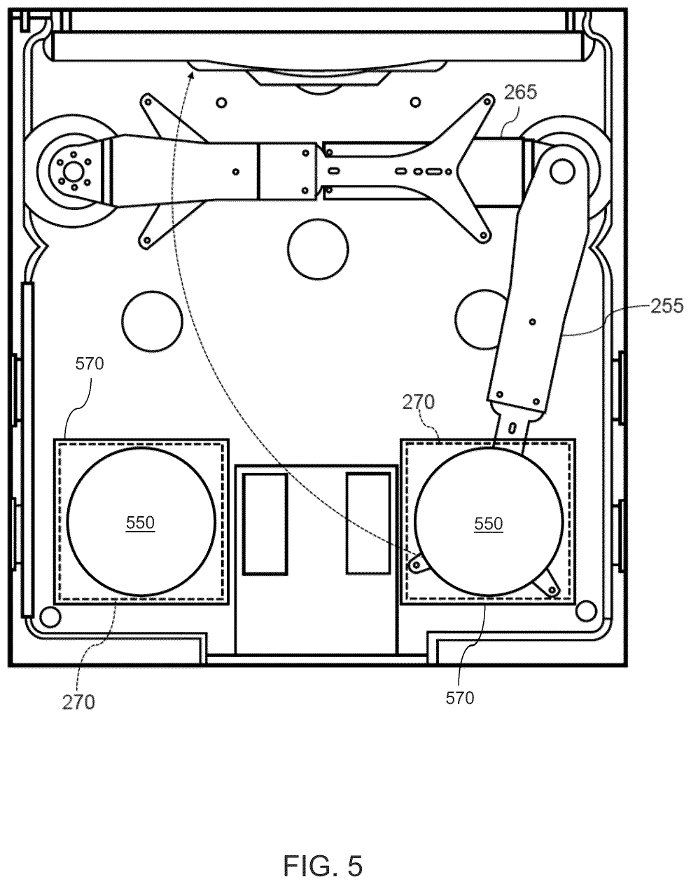

Referring now to FIG. 5, another thermal processing assembly 570 according to example embodiments of the present disclosure is provided. Specifically, FIG. 5 illustrates a top down internal view of a load lock chamber according to example embodiments of the present disclosure. Thermal processing assembly 570 may thermally process a workpiece 550 when the workpiece 550 is positioned, for example, within a thermal processing region 270 of a load lock chamber, such as load lock chamber 200 of FIG. 2. Specifically, thermal processing assembly 570 may be configured to cool a workpiece 550. As shown in FIG. 5, thermal processing assembly 570 may be a cooling device, such as a cooling pedestal or cooling plate defining a thermal processing region 270 (e.g., cooling station) within a load lock chamber. For example, thermal processing assembly 570 may be positioned below workpiece 550, such as on a bottom, internal surface of the load lock chamber. In some embodiments, a load lock chamber may include two thermal processing assemblies 570. As such, two workpieces 550 may be thermally processed (e.g., cooled) simultaneously within a load lock chamber.

In some embodiments, workpiece 550 may be provided to thermal processing assembly 570 (e.g., cooling device, cooling pedestal, cooling plate, etc.) by arm 255 (e.g., an end effector of arm 255). Accordingly, workpiece 550 may be placed (e.g., dropped) onto, for example, a lift device (e.g., lift pins, indexer arm, etc.) that will position the workpiece 550 on thermal processing assembly 570 where the workpiece 550 may be cooled. In further embodiments, arm 255 may be moved (e.g., retracted) to a home position, such as the position defined by arm 265 in FIG. 5, during thermal processing (e.g., cooling) of the workpiece 550.

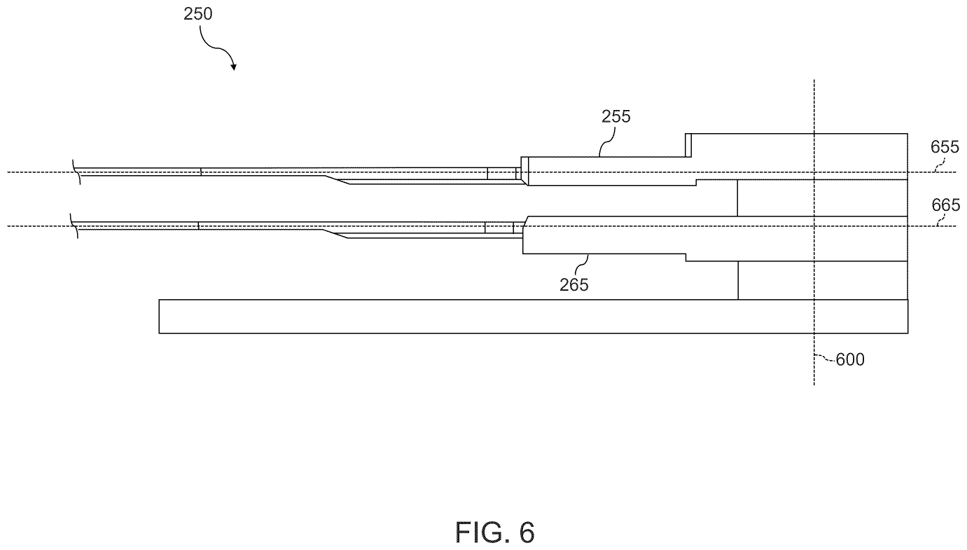

FIG. 6 depicts an example workpiece handling robot according to example embodiments of the present disclosure. Workpiece handling robot 250 is defined within a load lock chamber, such as load lock chamber 200 of FIG. 2. As previously described with reference to FIG. 2, workpiece handling robot 250 includes an arm 255 configured to transfer a workpiece to and from a thermal processing region within a load lock chamber. Workpiece handling robot 250 may further include arm 265 also configured to transfer a workpiece to and from a thermal processing region within a load lock chamber. Arms 255, 265 may rotate about a shared axis 600. As shown in FIG. 6, arm 255 may be defined above arm 265 relative to axis 600. As such, arm 255 may move (e.g., rotate about axis 600) along a first plane 655 while arm 265 may move (e.g., rotate about axis 600) along a second plane 665. As shown in FIG. 6, both planes 655, 665 may be perpendicular to axis 600.

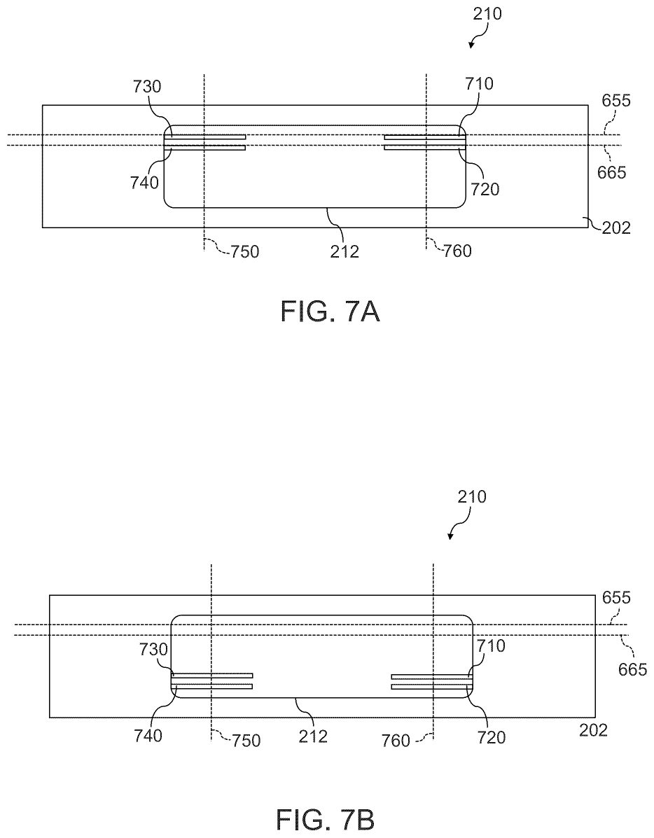

Referring now to FIGS. 7A and 7B, a workpiece support 210 according to example embodiments of the present disclosure are provided. As discussed previously with reference to FIG. 2, workpiece support 210 may include one or more movable shelves. As shown in FIGS. 7A and 7B, workpiece support 210 may be aligned with opening 212 of sidewall 202. Workpiece support 210 may include one or more movable shelves 710, 720, 730, 740. Shelves 710, 720, 730, 740 are movable along axes 760, 750. For example, shelves 710, 720, 730, 740 may move in an first direction (e.g., up) and a second direction (e.g., down) along axes 760, 750. Axes 760, 750 may be perpendicular to the one or more planes that define the movement of the one or more arms of a workpiece handling robot. For example, axes 760, 750 may be perpendicular to planes 655 and/or 665 described with reference to FIG. 6.

Specifically, FIG. 7A depicts shelves 710, 720, 730, 740 in an up position. The positioning of the shelves 710, 720, 730, 740 in the up position may be defined by (e.g., intersect) the one or more planes 655, 665 that define the movement of the one or more arms. For example, shelves 710, 720, 730, 740 may be moved to the up position so that an end effector of a workpiece handling robot may retrieve a workpiece from the shelf. In some embodiments, shelf 710 may be accessible by a first arm (e.g., end effector of a first arm) of a workpiece handling robot while shelf 720 may be accessible by a second arm (e.g., end effector of a second arm) of the same workpiece handling robot while in the up position as shown in FIG. 7A. In further embodiments, shelf 730 and shelf 740 may be similarly accessible by a different workpiece handling robot while in the up position.

FIG. 7B depicts shelves 710, 720, 730, 740 in a down position. The positioning of the shelves 710, 720, 730, 740 in the down position may not be defined by (e.g., not intersect) the one or more planes 655, 665 that define the movement of the one or more arms. For example, shelves 710, 720, 730, 740 may be moved to the down position such that the arms of one or more workpiece handling robots may move freely about the load lock chamber, such as from a thermal processing region to the process chamber.

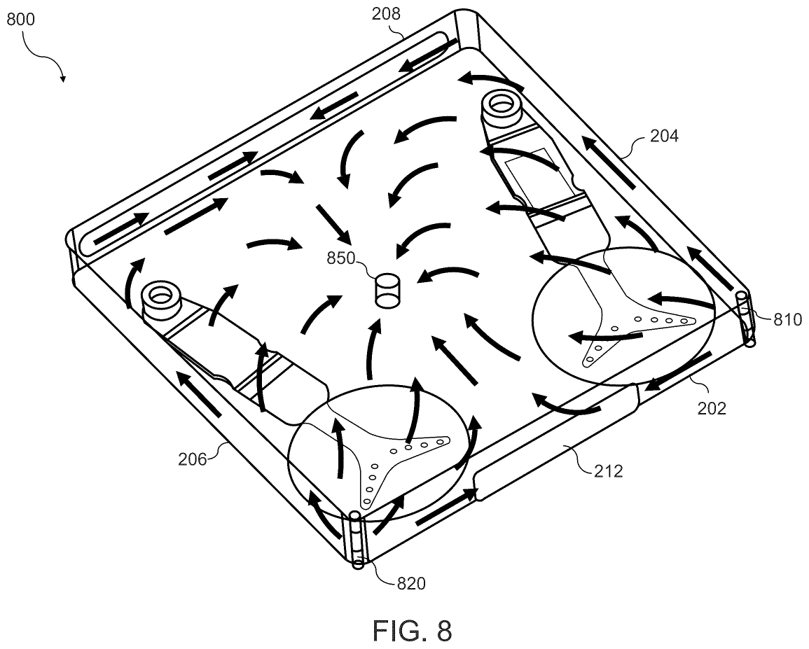

FIG. 8 depicts an example gas system according to example embodiment of the present disclosure. Gas system 800 of FIG. 8 may be implemented in a load lock chamber, such as load lock chamber 200 of FIG. 2. Gas system 800 may be defined as a purge gas system, configured to provide and exhaust purge gas from a load lock chamber.

As shown in FIG. 8, gas system 800 includes one or more purge gas inlets 810, 820 configured to provide the purge gas to the load lock chamber. Gas inlets 810, 820 may be positioned proximate a corner of the load lock chamber. For example, gas inlet 810 may be positioned proximate a corner defined at the intersection of sidewall 204 and sidewall 202. Further, gas inlet 820 may be positioned proximate a corner defined at the intersection of sidewall 206 and sidewall 202. As previously described, sidewall 202 may include opening 212 (e.g., slit, slit door) through which a workpiece may be transferred from, for example, a front end module such as front end portion 120 of FIG. 1. Accordingly, gas inlets 810, 820 may be defined to be positioned on each side of opening 212 along sidewall 202. In some embodiments, gas system 800 may further include other gas inlets, such as gas inlets positioned proximate other corners of a load lock chamber. For example, gas system 800 may include a gas inlet at each corner of the load lock chamber in some embodiments.

Gas system 800 further includes a purge gas outlet 850 configured to exhaust purge gas from the load lock chamber. Purge gas outlet 850 may be positioned proximate the center of the load lock chamber. The purge gas outlet 850 may defined within a lower surface of the load lock chamber. For example, purge gas outlet 850 may be defined on a surface of the load lock chamber opposite a lid of the load lock chamber.

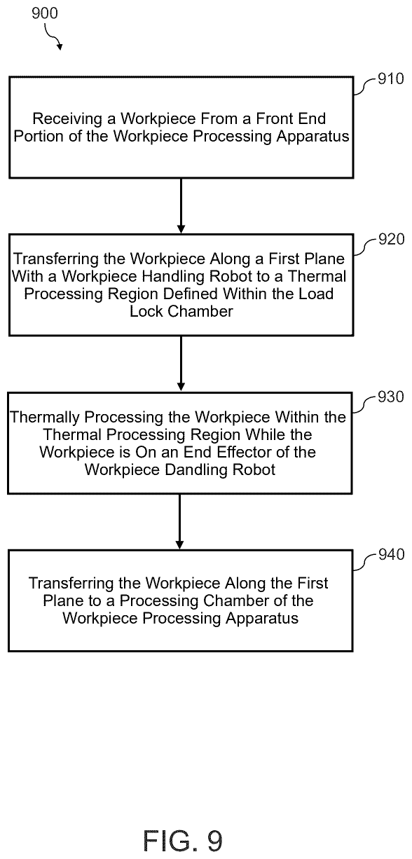

FIG. 9 depicts an example method 900 for thermally processing a workpiece within a load lock chamber according to example embodiments of the present disclosure. While method 900 is discussed with reference to load lock chamber 200 as described throughout the present disclosure, those of ordinary skill in the art will understand that method 900 may be used to thermally process a workpiece in any applicable load lock chamber without deviating from the scope of the present disclosure.

At 910, method 900 includes receiving a workpiece from a front end portion of the workpiece processing apparatus. For example, load lock chamber 200 may receive a workpiece from front end portion 120.

At 920, method 900 includes transferring the workpiece along a first plane with a workpiece handling robot to a thermal processing region defined within the load lock chamber. For example, workpiece handling robot 250 may transfer a workpiece along a first plane 655 to a thermal processing region 270 defined within load lock chamber 200.

At 930, method 900 includes thermally processing the workpiece within the thermal processing region while the workpiece is on an end effector of the workpiece handling robot. For example, thermal processing assembly 350 may thermally process (e.g., heat) a workpiece when the workpiece is on an end effector 257 of workpiece handling robot 250.

At 940, method 900 includes transferring the workpiece along the first plane to a processing chamber of the workpiece processing apparatus. For example, a workpiece handling robot 250 may transfer a workpiece along first plane 655 to processing chamber 110 of workpiece processing apparatus 100.

One example aspect of the present disclosure is directed to a load lock chamber of a workpiece processing apparatus. The load lock chamber includes a workpiece handling robot comprising a first arm configured to transfer a workpiece along a first plane to and from a thermal processing region defined within the load lock chamber. The load lock chamber further includes a thermal processing assembly configured to thermally process the workpiece when the workpiece is positioned within the thermal processing region defined within the load lock chamber. The workpiece handling robot is further configured to transfer the workpiece along the first plane to a processing chamber of the workpiece processing apparatus.

In some examples, the workpiece handling robot further includes a second arm configured to transfer a second workpiece along a second plane to and from the thermal processing region.

In some examples, the load lock chamber further includes a workpiece support defined within the load lock chamber, the workpiece support comprising one or more shelves configured to hold one or more workpieces. The one or more shelves are movable along an axis perpendicular to the first plane.

In some examples, the one or more shelves of the workpiece support are movable to a first position defined by the first plane and a second position not defined by the first plane.

In some examples, the thermal processing assembly includes a light source assembly configured to heat the workpiece through a window of the load lock chamber while the workpiece is on an end effector of the workpiece handling robot.

In some examples, the thermal processing assembly includes a cooling device configured to cool the workpiece.

In some examples, the load lock chamber further includes one or more purge gas inlets positioned proximate at least one corner of the load lock chamber and a purge gas outlet positioned proximate a center of the load lock chamber.

In some examples, the load lock chamber is positioned between a front end portion of the workpiece processing apparatus and the processing chamber of the workpiece processing apparatus.

In some examples, the processing chamber includes a first processing position and a second processing position. The workpiece handling robot is further configured to transfer the workpiece along the first plane to the first processing position of the processing chamber.

Another example aspect of the present disclosure is directed to a method for thermally processing a workpiece within a load lock chamber of a workpiece processing apparatus. The method includes receiving a workpiece from a front end portion of the workpiece processing apparatus. The method further includes transferring the workpiece along a first plane with a workpiece handling robot to a thermal processing region defined within the load lock chamber. The method further includes thermally processing the workpiece within the thermal processing region while the workpiece is on an end effector of the workpiece handling robot. The method further includes transferring the workpiece along the first plane to a processing chamber of the workpiece processing apparatus.

In some examples, the workpiece is received from the front end portion at a workpiece support of the load lock chamber, the workpiece support being movable along an axis perpendicular to the first plane.

In some examples, the method further includes moving the workpiece support along an axis perpendicular to the first plane to a first positioned defined by the first plane and moving the workpiece support along an axis perpendicular to the first plane to a second positioned not defined by the first plane.

In some examples, thermally processing the workpiece within the thermal processing region includes heating the workpiece through a window of the load lock chamber with a light source assembly, the window corresponding to the thermal processing region.

In some examples, the workpiece is transferred to a first processing position of the processing chamber, the processing chamber including a first processing position and a second processing position.

In some examples, the method further includes providing purge gas to the load lock chamber by one or more purge gas inlets positioned proximate at least one corner of the load lock chamber and exhausting purge gas from the load lock chamber by a purge gas outlet positioned proximate a center of the load lock chamber.

Another example aspect of the present disclosure is directed to a workpiece processing apparatus. The workpiece processing apparatus includes a front end portion configured to house one or more workpieces. The workpiece processing apparatus further includes a processing chamber comprising a first processing position. The workpiece processing apparatus further includes a load lock chamber. The load lock chamber includes a first workpiece handling robot configured to transfer a first workpiece along one or more first planes to and from a first thermal processing region defined within the load lock chamber. The load lock chamber further includes a first thermal processing assembly configured to thermally process the first workpiece when the first workpiece is positioned within the first thermal processing region defined within the load lock chamber. The first workpiece handling robot is further configured to transfer the first workpiece along the one or more first planes to the processing chamber of the workpiece processing apparatus.

In some examples, the load lock chamber further includes a second workpiece handling robot configured to transfer a second workpiece along one or more second planes to and from a second thermal processing region defined within the load lock chamber.

In some examples, the load lock chamber further includes a second thermal processing assembly configured to thermally process the second workpiece when the second workpiece is positioned within a second thermal processing region defined within the load lock chamber.

In some examples, the processing chamber further includes a second processing position. The second workpiece handling robot is further configured to transfer the second workpiece to the second processing position of the processing chamber.

In some examples, the load lock chamber further includes a workpiece support. The workpiece support includes one or more first shelves configured to provide one or more workpieces to the first workpiece handling robot, the one or more first shelves being movable along a first axis perpendicular to the one or more first planes. The workpiece support further includes one or more second shelves configured to provide one or more workpieces to the second workpiece handling robot, the one or more second shelves being movable along a second axis perpendicular to the one or more second planes.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A load lock chamber of a workpiece processing apparatus, the load lock chamber comprising:
a workpiece handling robot comprising a first arm configured to transfer a workpiece along a first plane to and from a thermal processing region defined within the load lock chamber; and
a thermal processing assembly configured to thermally process the workpiece when the workpiece is positioned within the thermal processing region defined within the load lock chamber,
wherein the workpiece handling robot is further configured to transfer the workpiece along the first plane to a processing chamber of the workpiece processing apparatus.

2. The load lock chamber of claim 1, wherein the workpiece handling robot further comprises:
a second arm configured to transfer a second workpiece along a second plane to and from the thermal processing region.

3. The load lock chamber of claim 1, further comprising:
a workpiece support defined within the load lock chamber, the workpiece support comprising one or more shelves configured to hold one or more workpieces,
wherein the one or more shelves are movable along an axis perpendicular to the first plane.

4. The load lock chamber of claim 3, wherein the one or more shelves of the workpiece support are movable to a first position defined by the first plane and a second position not defined by the first plane.

5. The load lock chamber of claim 1, wherein the thermal processing assembly comprises:
a light source assembly configured to heat the workpiece through a window of the load lock chamber while the workpiece is on an end effector of the workpiece handling robot.

6. The load lock chamber of claim 1, wherein the thermal processing assembly comprises:
a cooling device configured to cool the workpiece.

7. The load lock chamber of claim 1, further comprising:
one or more purge gas inlets positioned proximate at least one corner of the load lock chamber; and
a purge gas outlet positioned proximate a center of the load lock chamber.

8. The load lock chamber of claim 1, wherein the load lock chamber is positioned between a front end portion of the workpiece processing apparatus and the processing chamber of the workpiece processing apparatus.

9. The load lock chamber of claim 1, wherein the processing chamber comprises:
a first processing position; and
a second processing position,
wherein the workpiece handling robot is further configured to transfer the workpiece along the first plane to the first processing position of the processing chamber.

10. A method for thermally processing a workpiece within a load lock chamber of a workpiece processing apparatus, the method comprising:
receiving a workpiece from a front end portion of the workpiece processing apparatus;
transferring the workpiece along a first plane with a workpiece handling robot to a thermal processing region defined within the load lock chamber;
thermally processing the workpiece within the thermal processing region while the workpiece is on an end effector of the workpiece handling robot; and
transferring the workpiece along the first plane to a processing chamber of the workpiece processing apparatus.

11. The method of claim 10, wherein the workpiece is received from the front end portion at a workpiece support of the load lock chamber, the workpiece support being movable along an axis perpendicular to the first plane.

12. The method of claim 11, further comprising:
moving the workpiece support along an axis perpendicular to the first plane to a first positioned defined by the first plane; and
moving the workpiece support along an axis perpendicular to the first plane to a second positioned not defined by the first plane.

13. The method of claim 10, wherein thermally processing the workpiece within the thermal processing region comprises:
heating the workpiece through a window of the load lock chamber with a light source assembly, the window corresponding to the thermal processing region.

14. The method of claim 12, wherein the workpiece is transferred to a first processing position of the processing chamber, the processing chamber comprising:
the first processing position; and
a second processing position.

15. The method of claim 10, further comprising:
providing purge gas to the load lock chamber by one or more purge gas inlets positioned proximate at least one corner of the load lock chamber; and
exhausting purge gas from the load lock chamber by a purge gas outlet positioned proximate a center of the load lock chamber.

16. A workpiece processing apparatus, comprising:
a front end portion configured to house one or more workpieces;
a processing chamber comprising a first processing position; and
a load lock chamber, comprising:
a first workpiece handling robot configured to transfer a first workpiece along one or more first planes to and from a first thermal processing region defined within the load lock chamber; and
a first thermal processing assembly configured to thermally process the first workpiece when the first workpiece is positioned within the first thermal processing region defined within the load lock chamber,
wherein the first workpiece handling robot is further configured to transfer the first workpiece along the one or more first planes to the processing chamber of the workpiece processing apparatus.

17. The workpiece processing apparatus of claim 16, wherein the load lock chamber further comprises:
a second workpiece handling robot configured to transfer a second workpiece along one or more second planes to and from a second thermal processing region defined within the load lock chamber.

18. The workpiece processing apparatus of claim 17, wherein the load lock chamber further comprises:
a second thermal processing assembly configured to thermally process the second workpiece when the second workpiece is positioned within a second thermal processing region defined within the load lock chamber.

19. The workpiece processing apparatus of claim 18, wherein the processing chamber further comprises:
a second processing position,
wherein the second workpiece handling robot is further configured to transfer the second workpiece to the second processing position of the processing chamber.

20. The workpiece processing apparatus of claim 17, wherein the load lock chamber further comprises:
a workpiece support comprising:
one or more first shelves configured to provide one or more workpieces to the first workpiece handling robot, the one or more first shelves being movable along a first axis perpendicular to the one or more first planes; and
one or more second shelves configured to provide one or more workpieces to the second workpiece handling robot, the one or more second shelves being movable along a second axis perpendicular to the one or more second planes.
